(19) United States
(12) Patent Application Publication
(10) Pub. No.: US 2003/0085401 A1
(43) Pub. Date: May 8, 2003

(54) Crystalline silicon thin film transistor panel for oeld and method of fabricating the same

(76) Inventors: Seung Ki Joo, Seongnam-si (KR); Seok-Woon Lee, Incheon (KR)

Correspondence Address: GRAYBEAL, JACKSON, HALEY LLP, 155 - 108TH AVENUE NE, SUITE 350, BELLEVUE, WA, 98004-5901, US

(21) Appl. No.: 10/290,076

(22) Filed: Nov. 6, 2002

(30) Foreign Application Priority Data
Nov. 6, 2001 (KR) 2001-68968

(51) Int. Cl. H01L 29/04; H01L 31/036; H01L 31/0376; H01L 31/20

(52) U.S. Cl. 257/59

(57) ABSTRACT

The present invention relates to a crystalline silicon TFT panel for LCD and a method of fabricating the same. According to the present invention, an addressing TFT, a pixel driving TFT and a storage capacitor, which include a crystalline silicon thin film, are formed at a pixel region of the TFT panel using MILC, and a driving transistor is also formed at a peripheral region of the TFT panel. Furthermore, two or more gate electrodes are formed at the addressing TFT for supplying current to the storage capacitor so as to effectively lower an off current of the addressing TFT. Thus, the present invention has an advantage in that semiconductor devices required in the pixel region and the peripheral region of the TFT panel for OLED can be simultaneously fabricated through a relatively simple process, and thus, an off current characteristic and an on current characteristic that are required in the pixel region and the peripheral region, respectively, can be simultaneously satisfied.

### PRIORITY CLAIM

This application claims priority from Korean patent application No. 2001-68968, filed Nov. 6, 2001, which is herein incorporated by reference.

### BACKGROUND OF THE INVENTION

1. Field of the Invention

The present invention relates to a crystalline silicon thin film transistor (TFT) panel for use in an organic electro luminescent display (OLED) and method of fabricating the same. More particularly, the present invention relates to a crystalline silicon TFT panel for a TFT LCD and method of fabricating the same, wherein a pixel transistor located at a pixel region of the TFT panel and a driving transistor located at a peripheral region are simultaneously formed from polysilicon, and a low off current (Ioff) characteristic of the transistor required in the pixel region and a high on current (Ion) characteristic of the transistor required in the peripheral region are all satisfied, using metal induced lateral crystallization (MILC).

2. Description of the Prior Art

An OELD panel is usually configured to have a condenser structure in which an organic luminescent layer is mounted between an external glass plate having a transparent glass and a transparent electrode used as an anode, and an interior glass plate with a metal electrode serving as a cathode deposited thereon. The OELD panel is a solid-state light-emitting device for allowing light to be emitted through the transparent electrode by applying voltage a light emitting layer between the electrodes. A liquid crystal display (LCD) including a widely used TFT LCD has a low response speed and a limited view angle. In particular, in a case where a dark backlight, which is not self-luminescent, is used, there is a problem that power consumption thereof is very high. On the other had, the OELD has a high response speed, high brightness and low power consumption, and allows an ultra thin design since it utilizes an organic electro luminescent material for performing self-luminescence when voltage is applied thereto. Thus, the OELD has attracted considerable attention as a next generation display means. Recently, the OELD has been usually used in compact potable devices such as mobile phones, PDAs, and liquid display screens for car stereo. Furthermore, since a research on a large scale OELD has been actively made, it is expected that the OELD can also be used as the display means for PC and TV, in the future, along with the TFT LCD. The present invention relates to a polycrystalline silicon TFT panel for use in the OELD. The general constitution and operation principle of the OELD are already well known in the art, and thus, a detailed description thereof will be omitted herein.

Similarly to the TFT LCD, the TFT panel with a thin film transistor formed on the transparent substrate made of glass etc. is generally used as a means for applying the voltage to the organic electro luminescent material in the OELD. Although the use of the crystalline thin film transistor is recently on an increasing trend, the thin film transistor formed in the pixel region of the LCD panel is generally a type of transistor in which amorphous silicon is used as an active layer. On the contrary, the crystalline thin film transistor is mostly used as the thin film transistor formed in the pixel region of the OELD. As described below, a pixel driving transistor as well as an addressing transistor should be formed in the pixel region of the OLED. Thus, the crystalline thin film transistor should be used for satisfying the operating characteristics required in the pixel driving transistor. Accordingly, a process of crystallizing the amorphous silicon thin film is generally added to a process of fabricating the TFT panel for use in the OELD.

Since the TFT panel for OELD uses the crystalline silicon thin film transistor, the pixel transistor and the peripheral circuit of the OELD can be simultaneously formed in a single TFT panel. That is, since the crystalline silicon constituting the active layer of the crystalline silicon TFT has good electron mobility, it can be used in the peripheral circuit such as the switching device of the OELD. Thus, the pixel transistor and the driving transistor can be simultaneously formed in the TFT panel. Further, since the crystalline silicon TFT has a self-aligned structure, a level shift voltage thereof is lower than that of the amorphous silicon TFT. Also, it is possible to form a CMOS circuit since an N channel and a P channel can be formed using the crystalline silicon in the crystalline silicon TFT. In addition, the process of fabricating the crystalline silicon TFT can be employed in a semiconductor production line since it is similar to the standard CMOS process for a silicon wafer.

FIG. 1 is a schematic view of the TFT panel for OLED 10 on which the pixel region 11 and the peripheral regions, i.e. the driving circuit region 12 are formed. Arrays of a plurality of pixels including the addressing transistor, a storage capacitor, the pixel driving transistor and the like are formed in the pixel region 11, and driving devices for driving the pixels are formed in the peripheral region 12. In the polycrystalline silicon TFT OLED, a hybrid-driving mode in which analog circuits such as an operation amplifier (OP amplifier) or a digital-analog converter (DAC), which it is difficult to fabricate using the polycrystalline silicon TFT, are used as separate integrated circuits and the switching device such as a multiplexer is formed on the substrate are usually employed instead of forming all the driving devices on the substrate.

FIG. 2a shows an example of an equivalent circuit of a unit pixel formed in the pixel region of the TFT panel 10 for use in a voltage-driven type OELD. Each of the unit pixels comprises a data bus line (Vd), a gate bus line (Vg), and an addressing (switching) TFT 21 including a gate connected to the gate bus line and a source and drain connected to the data bus line. Further, the drain of the addressing TFT 21 is connected in parallel with the storage capacitor 22 for maintaining a state of a signal applied to the addressing TFT until a next signal is applied, and a gate of the pixel driving TFT 23 for receiving reference voltage (Vdd) to output driving voltage (Vc) of the organic electro luminescent material. As for TFT LCD, only one pixel TFT for applying the voltage to the pixel electrode is used in the unit pixel since the TFT LCD is not self-luminescent. However, as for the OELD, the pixel driving TFT 23 for receiving the output of the addressing TFT 21 as the gate signal is additionally used since the OELD cannot obtain a predetermined level of voltage enough to induce a luminescent phenomenon of the organic electro luminescent material only with data signal voltage.

FIG. 2b shows an example of an equivalent circuit diagram of a unit pixel formed in the pixel region of the TFT panel 10 for use in a current-drive type OELD. Two addressing TFTs 24, 25, two pixel driving TFTs 27, 29, and a storage capacitor 26 are formed in the unit pixel of the TFT panel for the current-driven type OELD. The first addressing TFT 24 is turned on by a signal from a first gate bus line (Vg1) to receive a signal from a data bus line (Vd). A second addressing TFT 25 is turned on by a signal from a second gate bus line (Vg2) to supply an output of the first addressing TFT 24 to gates of the pixel driving TFTs 27, 28 and the storage capacitor 26. If the first addressing TFT 24 and the second addressing TFT 25 are turned on, electric charges are accumulated at the storage capacitor 26 in which voltage is in turn generated. Then, the driving voltage is applied to the gates of the first and second pixel driving TFTs 27, 28. Even though the second addressing TFT 25 is turned off, the voltage applied to the storage capacitor maintains a turn-on state of the pixel driving transistors 27, 28 until a next signal period so that a driving current can be continuously supplied to the unit pixel of the OELD.

As for the crystalline silicon TFT panel for OELD in which the pixel region and the peripheral region are simultaneously formed in the common substrate, it is required that the pixel region have the low off current (Ioff), i.e. a current flowing into the pixel transistor (Hereinafter, the pixel transistor of the OELD should be regarded as including the addressing TFT and pixel driving TFT, unless referred to the contrary.) in a state where a gate voltage is not applied, whereas the peripheral region have the high on current (Ion), i.e. a current flowing into the thin film transistor in a state where the gate voltage is applied, in order to effectively drive the driving device such as the switching device. As for the TFT panel for OELD, the off current of the thin film transistor for directly supplying current to the storage capacitor should be preferably lower than 1E-11 A, particularly as in the addressing TFT 21 of FIG. 2a and the second addressing TFT 25 of FIG. 2b. If the off current of the addressing TFT is greater than 1E-11 A, even though the outputs from the addressing TFT 21 of FIG. 2a and the second addressing TFT 25 of FIG. 2b are applied to generate potentials in the storage capacitors 22, 25, respectively, the accumulated electric charges cannot be maintained until the next signal period. Therefore, there are problems that the potentials applied to the gates of the pixel driving TFTs cannot be maintained and thus the turn-on state of the pixel driving TFT cannot also be maintained.

The thin film transistor of the TFT panel for use in the polycrystalline silicon OELD is fabricated by forming an amorphous silicon layer on the glass substrate and then crystallizing the amorphous silicon by means of solid phase crystallization, laser crystallization, direct deposition method, rapid thermal annealing, or the like. One of the characteristics of the present invention is that a method of crystallizing the active layer of the thin film transistor using the metal induced lateral crystallization (MILC) is used instead of the existing method of crystallizing the amorphous silicon. If the MILC is used, there is an advantage in that the crystalline silicon TFT can be simultaneously formed at the pixel region and the peripheral region through a simple process at a relatively low temperature as compared with the existing crystallization method. However, similarly to the crystalline silicon crystallized by another method, the crystalline silicon crystallized by the MILC exhibits a high off current as compared with the amorphous silicon. In particular, in order to preserve electrical signals accumulated at the storage capacitor without any loss during a select signal period, it is generally required that the off current be lower than 1E-11 A. However, the crystalline silicon TFT which has been formed using the MILC exhibits a good on current characteristic and a poor off current characteristic (that is, the off current is relatively high). Thus, there is another problem in that the thin film transistor characteristic required in the pixel region of the OELD cannot be satisfied.

Accordingly, there are needs for a structure of the polycrystalline silicon TFT panel for OELD and method of fabricating the same, in which the polycrystalline silicon TFT is effectively formed at the pixel region and the peripheral region of the TFT panel for OELD at the same time, and the low off current required in the pixel region and the high on current required in the peripheral regions are simultaneously satisfied

### SUMMARY OF THE INVENTION

The present invention is conceived to solve the problems in the prior art. An object of the present invention is to provide a thin film transistor (TFT) panel for OELD and method of fabricating the same, wherein a pixel transistor and a driving transistor including a polycrystalline silicon active layer are simultaneously formed at a pixel region and a peripheral region, respectively, of the TFT panel for OELD using metal induced lateral crystallization (MILC), and an off current characteristic and an on current characteristic that are required in the pixel region and the peripheral region, respectively, are simultaneously satisfied.

### BRIEF DESCRIPTION OF THE DRAWINGS

FIG. 1 is a schematic view showing region positioning of a TFT panel for OLED;

FIG. 2a is an equivalent circuit diagram illustrating a structure of a unit pixel in the TFT panel for use in a voltage-driven type OELD;

FIG. 2b is an equivalent circuit diagram illustrating a structure of a unit pixel in the TFT panel for use in a current-driven type OELD;

FIGS. 3a to 3d are sectional views illustrating a conventional method of fabricating a thin film transistor using MILC;

FIG. 4 is a graph illustrating variation in a drain current depending on the number of a gate in the TFT fabricated using the MILC; and

FIGS. 5a to 5q are views illustrating a process of fabricating a crystalline silicon TFT panel for OLED according to the present invention.

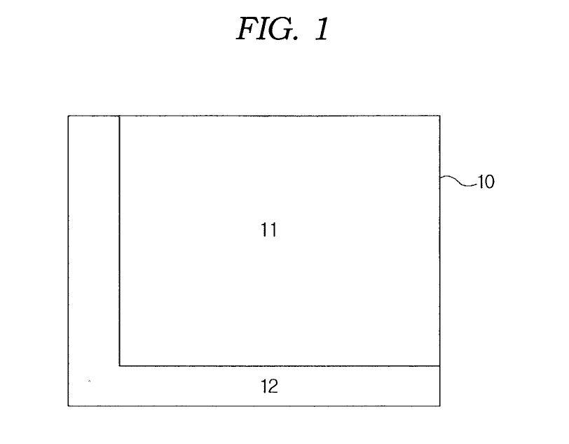

### DESCRIPTION OF THE PREFERRED EMBODIMENTS

Before explaining the specific constitution of the present invention, a process of forming a crystalline silicon thin film transistor using MILC will be now described below.

A thin film transistor for use in a display device such as OELD is usually constructed in such a manner that silicon is deposited on a transparent substrate made of glass, quartz, or the like; gates and gate electrodes are formed thereon; dopants are implanted into source and drain regions and are activated in a process of annealing; and then an insulating layer is formed thereon. An active layer for constituting the source and drain regions and a channel of the thin film transistor is generally formed by depositing a silicon layer onto the transparent substrate made of glass using a chemical vapor deposition (CVD) method, sputtering, and the like. In general, the TFT panel for use in the OELD is composed of crystalline silicon in order to satisfy an operating characteristic required in the OELD. Thus, a technology in which amorphous silicon is annealed and crystallized to be the crystalline silicon having high electron mobility has been used when fabricating the TFT panel for OELD.

Various methods for crystallizing the amorphous silicon layer into the crystalline silicon layer of the thin film transistor have been proposed. Solid phase crystallization (SPC) is a method for annealing the amorphous silicon layer for several hours to several tens of hours at a temperature of about 600° C. or lower that is a transition temperature of glass used for forming the substrate. Since the SPC method requires a long period of time for thermal annealing the silicon layer, there is a problem in that productivity thereof is low. Further, if the substrate has a large area, the substrate may be deformed during the process of long thermal annealing even at a temperature of 600° C. or lower. Excimer laser crystallization is a method for instantaneously crystallizing the silicon layer by scanning the silicon layer using the excimer laser beam onto to generate high temperature thereon locally for a very short period of time. The ELC method has a technical difficulty in precisely controlling the scanning of the laser beam and can fabricate only one substrate at one time. Therefore, there is also a problem in that productivity of the ELC method becomes lower than a case where several substrates are batch processed in a furnace.

In order to overcome the shortcoming of the conventional method for crystallizing the silicon layer, it is utilized a phenomenon in which a phase change of the amorphous silicon into the crystalline silicon is induced even at a low temperature of about 200° C. when metals such as nickel, gold and aluminum come into contact with or implanted into the amorphous silicon. Such a phenomenon is called as metal induced crystallization (MIC). In a case where the thin film transistor has been fabricated using the MIC phenomenon, any metal remains in the polysilicon for constituting the active layer of the thin film transistor. Thus, there is a problem in that current leakage occurs particularly at the channel of the thin film transistor. Recently, there has been proposed a method for crystallizing the silicon layer using metal induced lateral crystallization (MILC) in which crystallization of the silicon is successively induced while silicide formed by reaction of the metal and silicon is continuously, laterally propagated, without allowing the metals to directly induce phase change of the silicon (S. W. Lee & S. K. Joo, IEEE Electron Device Letter, 17(4), p. 160, 1996). Nickel, palladium, and the like are specifically known as the metals for inducing the MILC. In a case where the silicon layer is crystallized using the MILC, a metal component used for inducing the crystallization of the silicon hardly remains within the silicon layer, which is crystallized through the MILC, since an interface of the metal-containing silicide propagates laterally as the crystallization of the silicon layer is propagated. Thus, there is an advantage in that the metals such as Ni and Pd have no influence on the current leakage characteristics and other operating characteristics of the active layer of the thin film transistor. In addition, by utilizing the MILC, the crystallization of the silicon can be induced even at a relatively low temperature of 300° C. to 500° C. Thus, there is another advantage in that the furnace can be used so that several sheets of the substrates are simultaneously crystallized without damage to the substrates. In addition, in a case where the MILC phenomenon is used, it is possible to induce crystallization of silicon even at a relatively low temperature of 300° C. to 600° C. Thus, there is an advantage in that several sheets of the substrates can be simultaneously crystallized using the furnace without any damage to the substrate even though a general glass substrate is used.

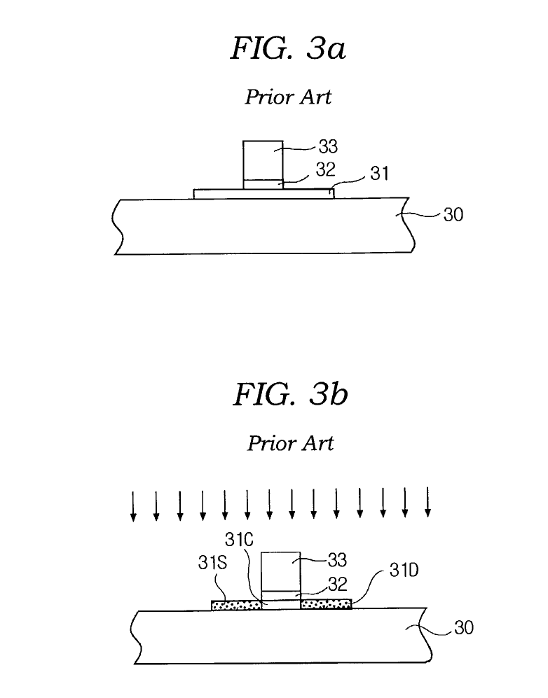

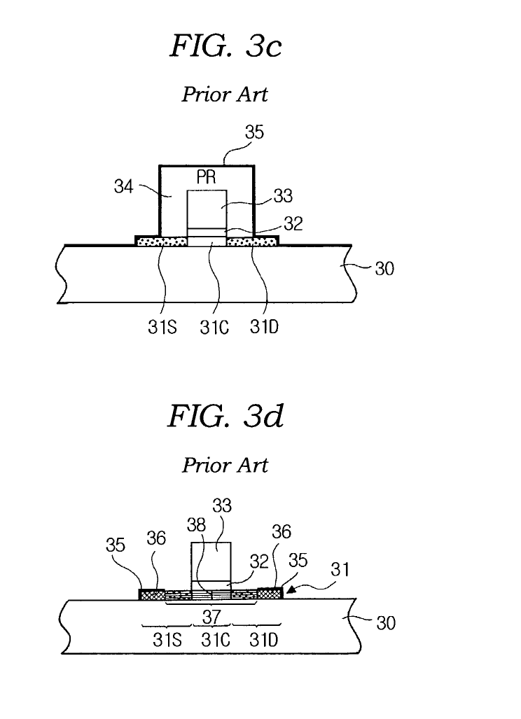

FIGS. 3a to 3d are sectional views showing a conventional process of crystallizing the silicon layer constituting TFT using the MIC and MILC phenomena. As shown in FIG. 3a, an amorphous silicon layer 31 is deposited on an insulating substrate 30 with a buffer layer (not shown) formed thereon. Then, amorphous silicon is patterned by photolithography to form an active layer 31. Next, a gate insulating layer 32 and a gate electrode 33 are sequentially formed on the active layer 31 by means of a general method. As shown in FIG. 3b, a source region 31S, a channel region 31C and a drain region 31D are formed on the active layer 31 by doping an impurity into an entire substrate in a state where the gate electrode 33 is used as a mask. As shown in FIG. 3c, a photoresist 34 (PR) is formed such that the gate electrode 33 and some portions of the source region 31S and the drain region 31D around the gate electrode are covered. A metal layer 35 is then deposited on an entire surface of the photoresist and substrate. As shown in FIG. 3d, the photoresist 34 is removed and the entire substrate is then annealed at a temperature of 300 to 600° C. Thus, a source and drain region 36 right below the remaining metal layer 35 is crystallized by the MIC phenomenon, whereas a metal-offset portion of the source and drain region and a channel region 37 just below the gate electrode are induced to be crystallized by means of the MILC phenomenon which will be induced from the remaining metal layer 35.

In FIGS. 3a to 3d, the reason that the photoresist is formed to cover the source and drain regions 31S, 31D at both sides of the gate electrode 33 is that the metal components introduced by the MIC phenomenon remains in the channel region 31C and at the boundaries between the channel region 31C and the source/drain regions 31S, 31D if the metal layer is deposited up to the boundaries and thus a leakage current from and an operating characteristic of the channel region may be degraded. Since the source and drain regions except for the channel region are not greatly affected by the remaining metal components in view of their operations, the source and drain regions spaced apart from the channel region by about 0.01 to 5 μm are caused to be crystallized through the MIC phenomenon while crystallization for only the channel region and the channel peripheral region is caused to be induced by the MILC phenomenon, so that crystallization time is reduced.

As can be seen from Table 1, in a case where when a single gate is used as shown in FIGS. 3a to 3d, the thin film transistor including the crystalline silicon active layer, which has been crystallized by the MILC phenomenon according to the method shown in the figures, has an on current of about 3.00E-4 A and an off current of about 5.00E-11 A. Therefore, the ratio of the on current and off current (Ion/Ioff) becomes about 6.00E+06. In general, if the off current of the pixel transistor used in the OELD, i.e. the addressing TFT for directly supplying the current to the storage capacitor is greater than 1E-11 A, the gate voltage of the pixel driving transistor cannot be constantly maintained and thus a problem such as defective contrast may be produced when an actual display is implemented. Consequently, since the crystalline silicon thin film transistor in which only one gate is employed in the polycrystalline silicon crystallized by the MILC has the off current greater than the aforementioned value of 1E-11 A, the crystalline silicon thin film transistor may be difficult to be used as the pixel transistor for the OELD, particularly as the addressing TFT. On the other hand, since as seen from Table 1, the on current is about 3.00E-4 A in a case where only one gate is used, it is greater than an on current range of 1E-05 A, which is generally required in the pixel transistor for the OELD. Therefore, if the crystalline silicon TFT formed by the MILC is to be used as the pixel transistor of the OELD, the off current should be kept less than 1E-11 A while maintaining the on current at a level greater than 1E-05 A.

In the crystalline silicon TFT fabricated using the MILC, if the number of the gate is increased, a junction distance between the source and drain regions is increased and intensity of an electric field applied to the junction region is accordingly weaken. Thus, it is possible to reduce the off current. Although the on current is reduced as the number of the gate becomes increased, a degree of reduction in the on current is significantly smaller than that of the off current. Table 1 below shows variations in the off current, the on current, and the ratio of the on current and the off current according to the increase in the number of the gate.

TABLE 1

| | Number of Gate | | |
|---|---|---|---|
| | 1 | 2 | 4 |
| Ioff(A) | 5.00E−11 | 8.00E−12 | 4.00E−13 |
| Ion(A) | 3.00E−04 | 2.00E−04 | 1.00E−04 |
| Ion/Ioff | 6.00E+06 | 2.50E+07 | 2.50E+08 |

(It is a measurement result when a width W of the transistor=10 μm, a length L thereof=6 μm, V_{D}=10V, Ion is measured at the gate voltage V_{G}=20V; and Ioff is measured at the gate voltage V_{G}=−5V)

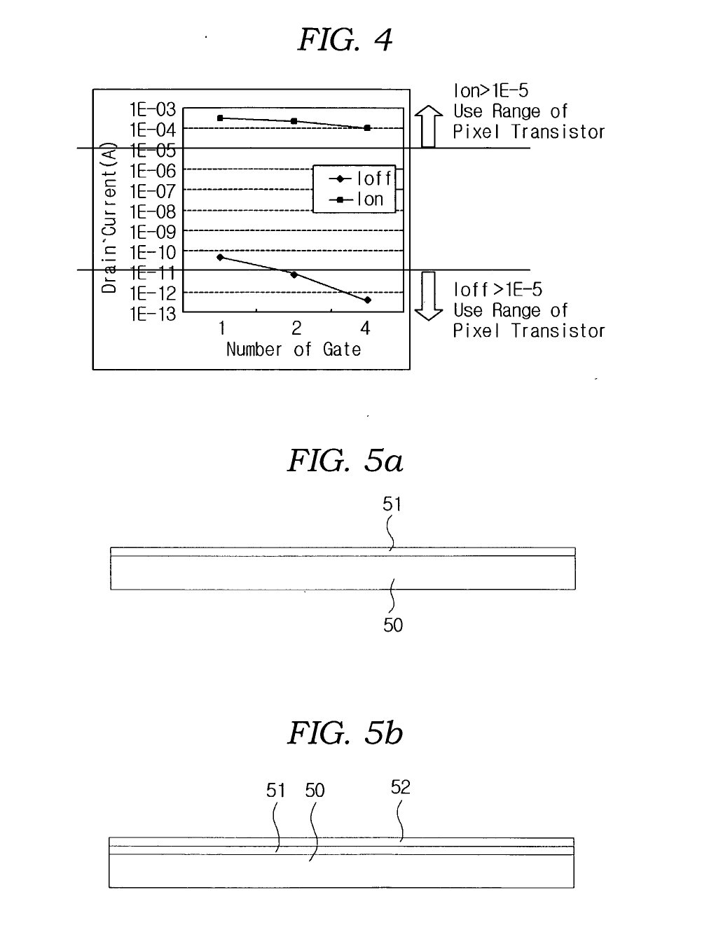

FIG. 4 is a graph illustrating the variations in the on current and off current according to the number of the gate depicted in Table 1. As seen from Table 1 and FIG. 4, if the number of the gate is increased to 2 and 4, the off current is changed to 8.00E-12 A and 4.00E-13 A, respectively. Thus, it will be understood that the off current, which is less than 1E-11 A required in the pixel transistor of the OELD (particularly, the addressing TFT), can be obtained if two or more gates are employed in the TFT. Meanwhile, it can be seen that the on current of 1.00E-04 A, which is greater than the on current 1E-5 A generally required in the pixel transistor of the OELD, can be obtained even when four gates are employed, because a rate of reduction in the on current according to the increase in the number of the gate is relatively low. Accordingly, it can be seen that the ratio of the on current and the off current (Ion/Ioff) is continuously increased as the number of the gate becomes increased. From the above results, it can be seen that the crystalline silicon TFT fabricated by the MILC according to the present invention can simultaneously satisfy the requirement characteristics of the on current and the off current in the pixel transistor of the OELD, i.e. Ion>1E-5 and Ioff<1E-11, if the two or more gates are used. Further, the on current corresponding to when the number of the gate shown in Table 1 and FIG. 4 is 2 or more has a current level enough to support the operation of the driving device formed at the peripheral region of the substrate. Thus, it can be seen that the method of fabricating the crystalline silicon TFT using the MILC according to the present invention can be preferably used to simultaneously form the pixel transistor on the pixel region and the driving transistor on the peripheral region of the LCD substrate, in a case where two or more gates are formed in the TFT of the pixel region.

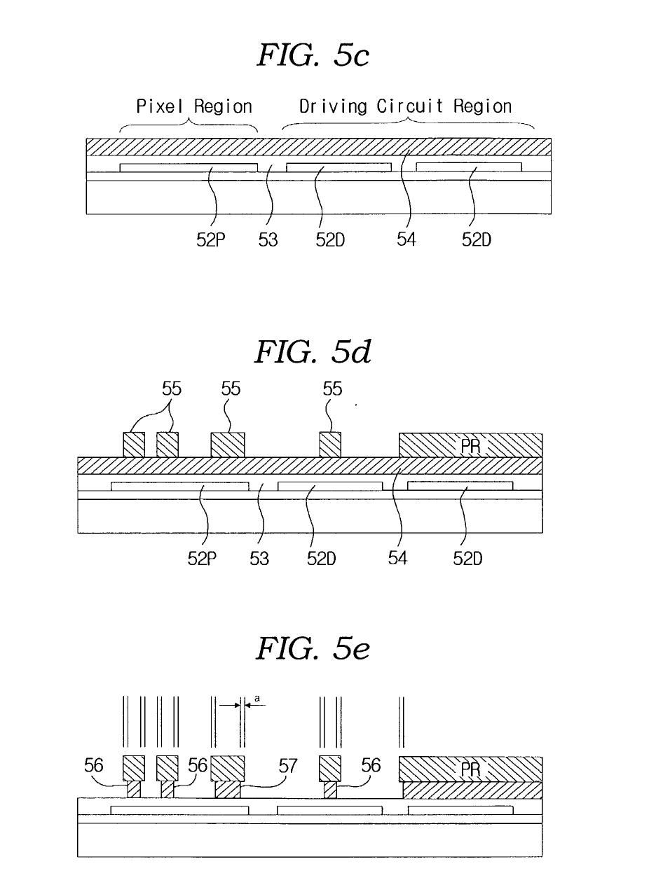

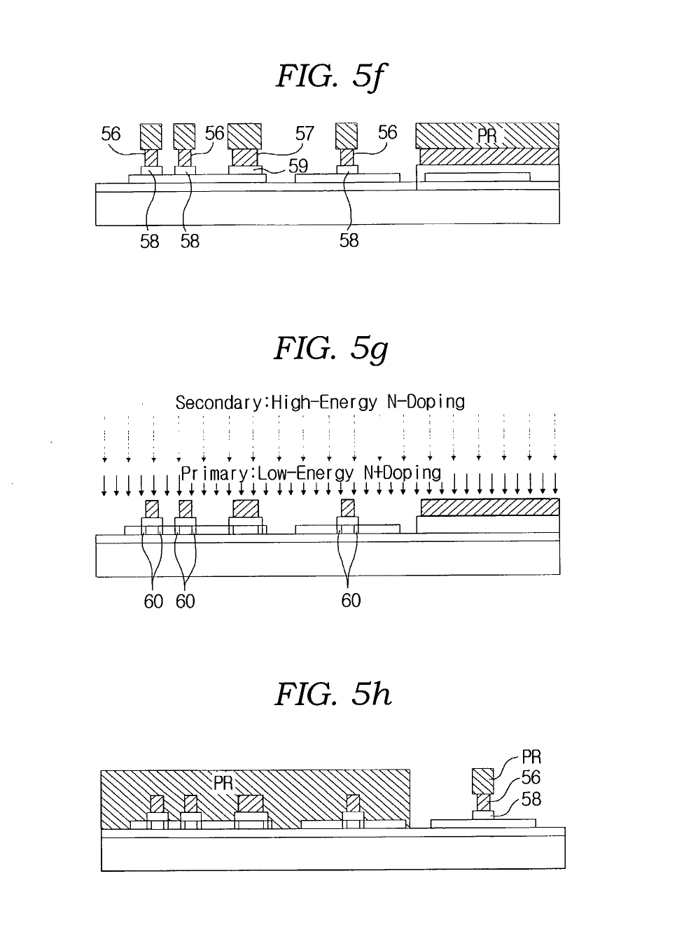

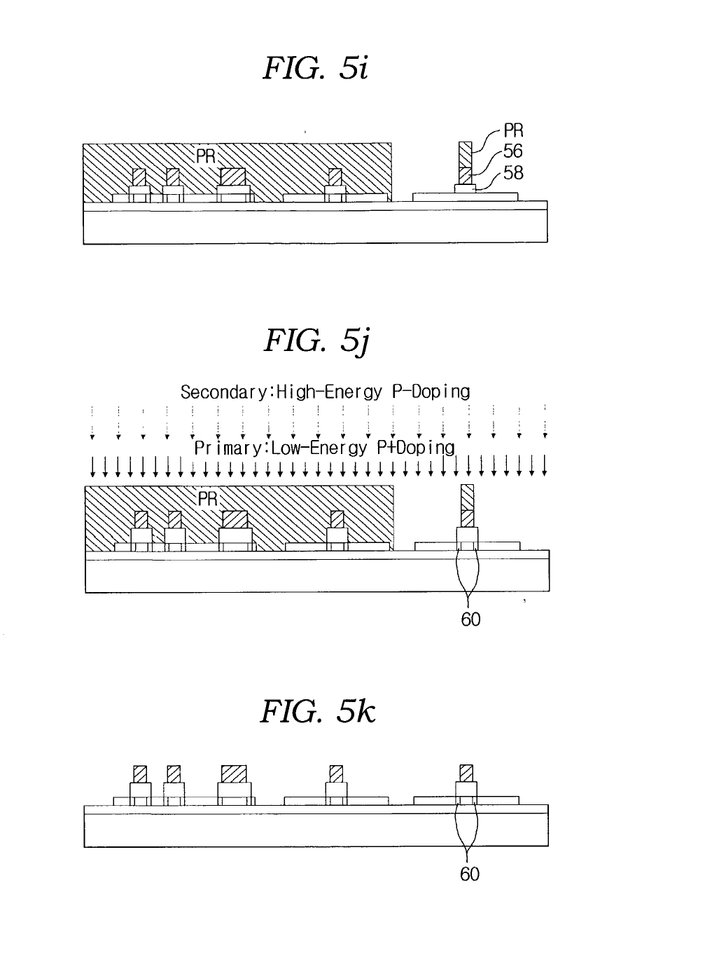

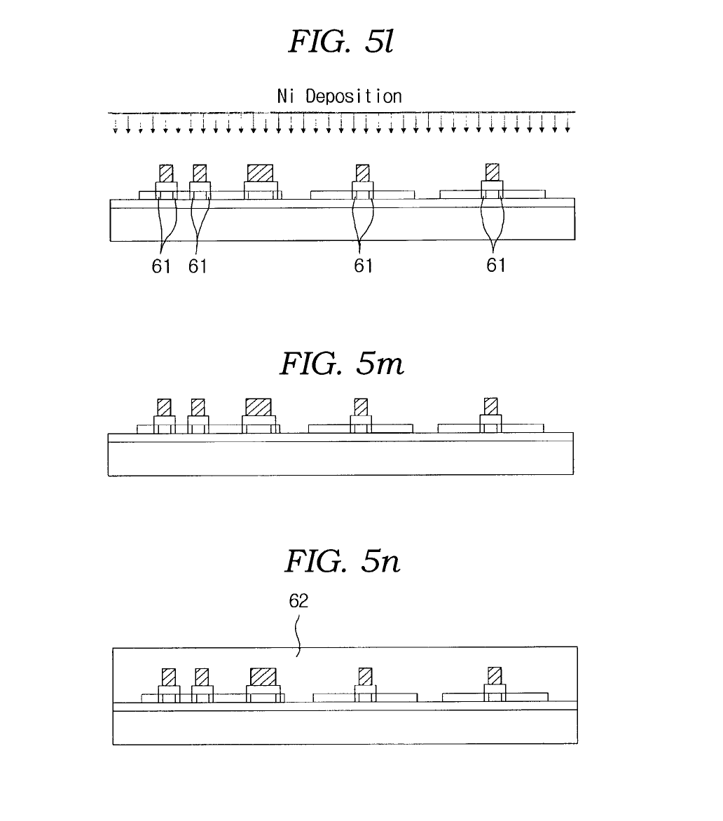

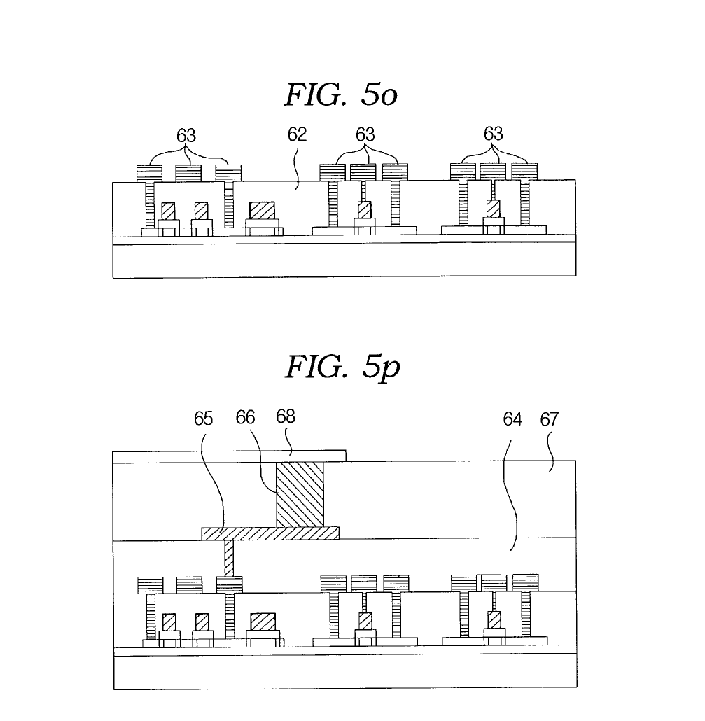

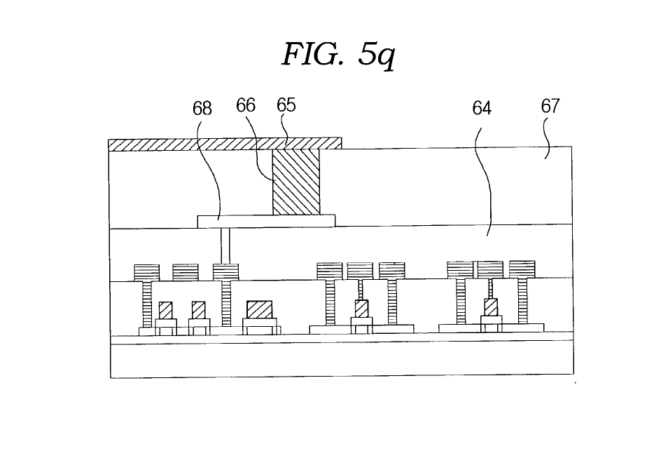

A process of simultaneously forming the pixel transistor and the driving transistor in the TFT panel using the MILC according to a preferred embodiment of the present invention will be hereinafter explained with reference to FIGS. 5a to 5q. Although an example in which one pixel transistor and one storage capacitor are formed in the pixel region and a CMOS transistor is formed in the peripheral region will be described below, it should be understood that the present invention is not limited thereto. According to the present invention, for example, two or more TFTs may be formed in the pixel region, and P-MOS, N-MOS, CMOS or combination thereof may be formed in the driving region. Further, although it has been described in a preferred embodiment that the silicon layers of the pixel transistor and the storage capacitor are connected with each other, it is apparent to those skilled in the art that the silicon layers of the pixel transistor and the storage capacitor need not necessarily be physically connected with each other but they may be configured to be electrically connected with each other. Furthermore, although it has been described in the preferred embodiment that an electrode of the storage capacitor is formed from the crystalline silicon, other layers such as the metal layer may be substituted for the electrode. Moreover, it is apparent to those skilled in the art that a dielectric layer of the storage capacitor may be formed from a layer that is made of a material different from the gate insulating layer, for example, an intermediate insulating layer.

FIG. 5a is a sectional view showing a state where a shield layer 51 for preventing diffusion of contaminants from a substrate 50 is formed on the substrate 50. Here, the substrate 50 is made of a transparent insulating material such as non-alkali glass, quartz, silicon oxide, or the like. The shield layer 51 is formed by depositing silicon oxide (SiO₂), silicon nitride (SiNx), silicon oxynitride (SiOₓN_{y}) or the composite material thereof at temperature of about 600° C. or lower and to thickness of 300 to 10,000 Å, more preferably 500 to 3,000 Å, using a deposition method such as plasma-enhanced chemical vapor deposition (PECVD), low-pressure chemical vapor deposition (LPCVD), atmospheric pressure chemical vapor deposition (APCVD), or electron cyclotron resonance CVD (ECR-CVD), or sputtering method.

As shown in FIG. 5b, an amorphous silicon layer 52 (a-Si) constituting the active layer of the thin film transistor is formed on the shield layer 51. The amorphous silicon layer 52 is formed by depositing the amorphous silicon to thickness of 100 to 3,000 Å, more preferably 500 to 1,000 Å, using the PECVD, LPCVD or sputtering method. Next, in order to form a N-MOS or a P-MOS in the pixel region and a CMOS used as the driving device in the peripheral region as shown in FIG. 5c, the amorphous silicon layer is patterned by dry etching using plasma of etching gas, by using the pattern formed by the photolithography.

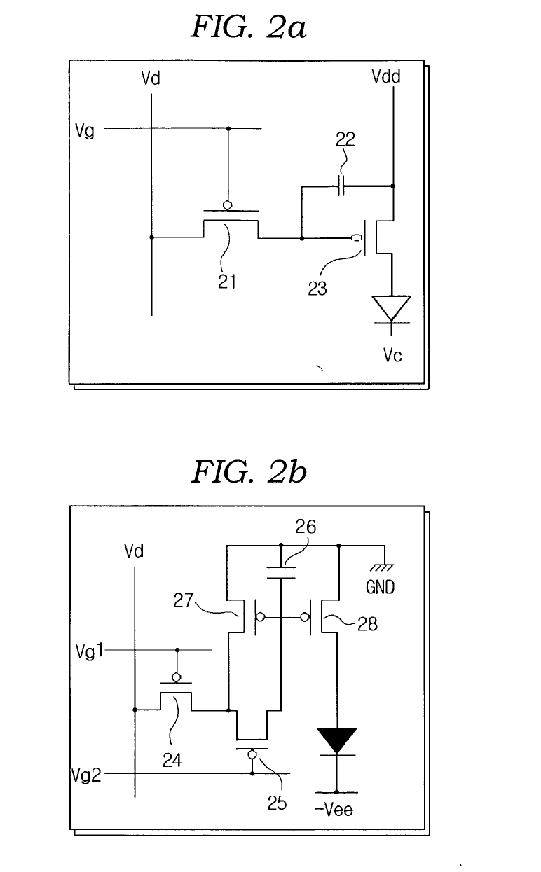

In FIG. 5b, the pixel region and the peripheral region are shown to be adjacent to each other. However, in an actual substrate, arrays of a plurality of unit pixels are formed in the pixel region, and a driving circuit is formed to be spaced apart from the unit pixel arrays. Meanwhile, it should be noted that one unit pixel region and one peripheral region are shown to be connected with each other in the figures, in order to illustrate the process of simultaneously forming the pixel transistor and the driving transistor. Further, FIG. 5b shows a structure in that a single amorphous silicon island 52P is formed in the pixel region in order to form a single N-MOS TFT or P-MOS TFT, whereas two amorphous silicon islands 52D are formed in the peripheral region in order to form the CMOS TFT. As described above, two thin film transistors, i.e. the addressing TFT and the pixel driving TFT are formed in the unit pixel of the voltage-driven type OELD. In the drawings, however, for convenience of simplicity, only the addressing TFT and the storage capacitor connected to the addressing TFT are shown in the unit pixel of the OELD, but the pixel driving TFT is not shown. Furthermore, although two addressing TFTs 24, 25 and two pixel driving TFTs 27, 28 are formed in the unit pixel of the current-driven type OELD in FIG. 2b, but only the addressing TFT 25 for directly supplying the current to the storage capacitor is shown in the figure together with the storage capacitor. It should be noted that the other pixel transistors are formed in the unit pixel of the OELD by the same method, unless referred hereinafter to the contrary. In addition, although it has been described in the preferred embodiment that the CMOS is formed in the peripheral region, it should be noted that various types of driving circuits such as N-MOS, P-MOS, CMOS or combination thereof can be formed in the peripheral region, if necessary.

After the amorphous silicon 52 is patterned, an insulating layer 53 in which a gate insulating layer will be formed and a metal layer 54 in which a gate electrode will be formed are formed as shown FIG. 5c. The insulating layer 53 is formed by depositing silicon oxide (SiO₂), silicon nitride (SiNx), silicon oxynitride (SiOₓN_{y}) or a composite layer thereof to thickness of 300 to 3,000 Å, preferably 500 to 1,000 Å, using the deposition method such as PECVD, LPCVD, APCVD, or ECR CVD. Further, the gate metal layer 54 is formed by depositing a metal material or a conductive material such as a doped polycrystalline silicon onto the insulating layer 53 to thickness of 1,000 to 8,000 Å, preferably 2,000 to 4,000 Å, using the method such as sputtering, evaporation, PECVD, LPCVD, APCVD, or ECR CVD.

FIGS. 5d and 5e show a process of forming a gate electrode 56 and a capacitor electrode 57 through a wet or dry etching process after forming photoresist patterns 55 which are formed through the photolithography onto the gate metal layer 54 located above an amorphous silicon island 52P in which the addressing transistor and the storage capacitor of the unit pixel will be formed and the amorphous silicon island 52D in which a driving transistor will be formed. As shown in the figures, three electrodes are formed in the pixel region, one gate electrode is formed above the amorphous silicon island 52D located at the left side of the peripheral region, and an entire surface of the amorphous silicon island region located at the right side of the peripheral region is covered by the photoresist (PR) so as to form other kinds of TFTs constituting the CMOS. Two left electrodes 56 among the three electrodes formed in the pixel region are used to form a dual gate electrode of the addressing transistor, and the other right electrode 57 is used as an electrode of the storage capacitor connected to the addressing transistor. In the preferred embodiment, the reason that the dual gate electrode is formed on the addressing transistor in the pixel region is that the off current can be further reduced since the junction between the source and drain regions is extended and the intensity of the electric field applied to the junction is weaken when multiple gates are used. Since the requirements on the low off current characteristic (less than 1E-11 A) for the pixel driving transistor or the transistor in the peripheral region are less severe than the addressing transistor, only a single gate can be employed in these transistors. However, it should be noted that the dual gate and/or two or more gates can be formed in all the transistors within the scope of the present invention.

As shown in FIG. 5e, the preferred embodiment of the present invention is configured to have an undercut structure by over etching the gate electrode 56 by a predetermined distance a inwardly of the patterned photoresist. As described below, the gate electrode layer is over etched so that a low-concentration doping region such as an LDD (lightly doped drain) region can be formed around the channel region below the gate electrode of the transistor.

FIG. 5f shows a state where a gate insulating layer 58 and a dielectric layer 59 of the capacitor have been formed by isotropically etching the insulating layer 53, using the patterned photoresist as a mask. Since the gate electrode has been over-etched against the photoresist as described above, the gate insulating layer 58 and the dielectric layer 59 are formed to have a width greater than that of the gate electrode 56 and the capacitor electrode 57 as shown in FIG. 5f.

FIG. 5g shows a process during which an impurity is doped using the gate electrode as a mask in a state where the photoresist has been removed. First, high-concentration impurity doping is performed with low energy onto the addressing transistor and the left driving transistor that is not covered by the photoresist. For example, if a N-MOS TFT is to be fabricated as shown in the figure, dopants such as PH₃, P, or As are doped at a dose of approximately 1E14 to 1E22/cm³ (preferably, 1E15 to 1E21/cm³) with energy of 10 to 100 KeV (preferably, 10 to 30 KeV), using an ion shower doping or ion implantation method. On the other hand, if a P-MOS TFT is to be fabricated, dopants such as B₂H₆, B, or BH₃ are doped at a dose of approximately 1E13 to 1E22/cm³ (preferably, 1E14 to 1E21/cm³) with energy of 10 to 70 KeV (preferably, 10 to 30 KeV). FIG. 5g shows a process of fabricating the N-MOS in the pixel region by implanting the N-type impurity. However, it should be noted that the P-MOS may be fabricated in the pixel region, if necessary. Since the high-concentration impurity is doped with low energy, it does not pass through the gate insulating layer. Thus, the source and drain regions of the thin film transistor are formed in a state where the impurity is implanted into only a region which is not covered by the gate insulating layer. According to the present invention, since the gate insulating layer in the addressing transistor is wider than the gate electrode and also serves to prevent the impurity doped at a high concentration with low energy from being implanted into the silicon layer, the low-concentration doping region having low impurity concentration can be formed around the channel region. Further, the gate insulating layer serves to form a metal offset region around the channel region, which will be described later.

After the low-energy high-concentration doping is performed, a high-energy low-concentration doping is performed. At this time, if the N-MOS TFT is to be fabricated, the high-energy low-concentration doping is performed in such a manner that the dopants such as PH₃, P and As at a dose of 1E11 to 1E20/cm³ with energy of 50 to 150 KeV, using the ion shower doping method, the ion implantation method or the other ion implantation methods. On the other hand, if the P-MOS TFT is to be fabricated, the high-energy low-concentration doping is performed in such a manner that dopants such as B₂H₆, B, and BH₃ at a dose of 1E11 to 1E20/cm³ with energy of 20 to 10 KeV. Since the low-concentration doping is performed with an energy level enough to allow the low-concentration impurity to pass through the gate-insulating layer, a low-concentration doping region 60 doped with the low concentration is formed at the active layer region covered by the gate-insulating layer.

Although it has been described that the low-energy high-concentration doping is performed and the high-energy low-concentration doping is then performed, it is apparent to those skilled in the art that a doping order may be changed. Meanwhile, if the high-concentration impurity is implanted with the high energy, the high-concentration impurity is injected into the silicon layer through the gate insulating layer. Therefore, the low-concentration doping region is not formed around the channel. Further, if the high-energy low-concentration doping process is omitted from the above process, an offset junction into which an impurity is not injected can be formed in the peripheral region of the thin film transistor channel, instead of the low-concentration doping region. Furthermore, in order to form the low-concentration doping region, the low-energy high-concentration doping method may be used instead of the high-energy low-concentration doping method. In such a case, the doping energy is controlled so that most of the impurities are confined within the insulating layer and only a portion of the impurities can be injected into the silicon layer.

If the low-concentration doping region or the offset junction is formed in the drain region adjacent the channel, the off current of the transistor can be reduced and the other electrical characteristics can also be stabilized. In order to accomplish these advantageous effects, it is preferred that the low-concentration doping region or the offset junction be configured to have a width of 1,000 to 20,000 Å, preferably 5,000 to 20,000 Å. It was found that to maintain the concentration of the impurity injected into the low-concentration doping region to be less than 1E14/cm² is particularly effective in reducing the off current of the pixel transistor to 1E-11 A or lower. Therefore, it is preferred that the impurity concentration in the low-concentration doping region be regulated to be less than 1E14/cm² by adjusting the doping energy and the dopant dose. As shown, although the low-concentration doping region may be formed both in the addressing transistor, the pixel driving transistor and the driving transistor, the low-concentration doping region may not be formed in the pixel driving transistor and the driving transistor since it is less necessary to critically limit the off current in the pixel driving transistor and the driving transistor as compared with the addressing transistor.

After the process of FIG. 5g has been completed, the gate insulating layer 58 and the gate electrode 56 are formed using the same method as described with reference to FIGS. 5d to 5f in order to form the P-type transistor at one side of the CMOS transistor, in a state that the entire pixel regions and the one transistor (N-type transistor in the preferred embodiment) located at the other side of the CMOS transistor formed in the driving region are covered with the photoresist (PR) as shown in FIG. 5h. Although it has been described in the preferred embodiment that the N-type transistor is first formed and the P type transistor is then formed in order to form the CMOS transistor of the driving region, it is apparent that the order of forming the transistors may be changed. As shown in FIG. 5i, the photoresist located above the gate electrode is then etched back so that the width of the photoresist is almost equal to that of the gate electrode.

Referring to FIG. 5j, after the gate insulating film and the gate electrode of the CMOS transistor located at the one side, i.e. the P type transistor are patterned as shown FIG. 5i, an impurity of an opposite polarity (i.e., P-type) to the other transistor constituting the CMOS transistor is first doped at high concentration with low energy and is then doped at low concentration with high energy, in the same manner as described with reference to FIG. 5g. As described above, the impurity doped at the low concentration with the high energy is injected into the silicon layer through the gate insulating layer, and thus, the low-concentration doping region is formed around the channel region of the P-type transistor. Of course, the execution order of the low-energy high-concentration doping and the high-energy low-concentration doping may be changed. In addition, the offset junction may be formed around the channel instead of the low-concentration doping region by omitting the high-energy doping process. Although it has been described in the preferred embodiment that the low-concentration doping region is formed in both the transistors in the pixel and peripheral regions, it should be noted that the low-concentration doping region may not be formed in the driving transistor since the driving transistor does not require the off current characteristic to a level necessary for the transistor in the pixel region.

FIG. 5k shows a state where the photoresist, which has been used as the mask in the doping process, has been removed; and FIG. 5l shows a process during which the photoresist is removed from the entire area of the pixel and driving regions on the substrate and a metal for inducing the MILC is then applied for crystallizing the amorphous silicon constituting the active layer of the transistor. Preferably, the metal for causing the MILC phenomenon to be induced into the amorphous silicon may include nickel (Ni) or palladium (Pd). Besides, Ti, Ag, Au, Al, Sn, Sb, Cu, Co, Cr, Mo, Tr, Ru, Rh, Cd, Pt or the like can be used. In the preferred embodiment, Ni is used as the metal for inducing the MILC. The metal for inducing the MILC such as Ni or Pd can be applied to the active layer through the sputtering, evaporation, PECVD or ion implantation method. But, the sputtering method is generally used. At this time, thickness of the applied metal layer may be arbitrarily selected within a range sufficient for inducing the MILC of the amorphous silicon layer, i.e. about 1 to 10,000 Å, preferably 10 to 200 Å.

As shown in FIG. 5l, a metal offset region 61 on which the metal for inducing the MILC is not deposited is formed around the channel region of each of the transistors on the substrate, because the gate insulating layer covers around the channel region. As already described with reference to FIGS. 3a to 3d, the metal offset region 61 serves to prevent a metal component, which is introduced into the silicon layer by means of the MIC phenomenon occurring at a region on which the metal for inducing the MILC such as Ni is directly deposited, from generating the current leakage in the channel region and degrading the operating characteristics. In the preferred embodiment, the gate insulating layer that has been patterned to be wider than the gate electrode serves to simultaneously form the low-concentration doping region and the metal offset region around the channel region. Therefore, the low-concentration doping region 60 and the metal offset region 61 are formed at the same region. Although it has been described in the preferred embodiment that the low-concentration doping region and the metal offset region are formed using the patterned gate insulating layer, it should be noted that the metal offset region may be formed by using the photoresist mask formed before the metal for inducing the MILC is applied, as shown in FIG. 3. Therefore, the low-concentration doping region and the metal offset region are not necessarily overlapped with each other at the same region, and the low-concentration doping region may be formed at a portion of the metal offset region or vice versa.

After Ni is applied on the transistors in the pixel and peripheral regions, an annealing process for crystallizing the active layer of the transistor is performed, as shown FIG. 5m. The crystallization-annealing process may be performed according to any given methods by which the MILC phenomenon can be induced into the amorphous silicon. The method may include, for example, a rapid thermal annealing (RTA) method in which the active layer is heated during a short period of time within several seconds to several minutes at a temperature of about 500 to 1200° C. using a tungsten-halogen or xenon arc heating lamp or an ELC method in which the active layer is heated during a very short period of time using an excimer laser. In the present invention, the crystallization of the silicon is preferably performed in a furnace at a temperature of 400 to 600° C. during 0.1 to 50 hours, more preferably during 0.5 to 20 hours. Since temperature when the amorphous silicon is crystallized in the furnace is lower than the glass transition temperature of the glass substrate, any transformation of or damage to the substrate can be prevented. Further, since a lot of the substrates can be simultaneously annealed in the furnace, mass processing of the substrate can be made. Therefore, the productivity thereof is increased. The crystallization at the amorphous silicon region to which the metal for inducing the MILC is directly applied through the annealing process is performed by the MIC phenomenon, whereas the crystallization at the portion to which the metal is not applied is performed by the MILC phenomenon propagated from the region to which the metal is applied. Further, according to the present invention, the crystallization of the active layer and the dopant may be performed in a single process since the annealing condition for crystallizing the amorphous silicon by means of the metal for inducing the MILC is similar to the annealing condition for activating the dopant injected into the active layer.

The amorphous silicon layer in the storage capacitor region, which is connected to the drain of the addressing transistor and formed at a lateral side of the addressing transistor, is simultaneously crystallized through the annealing process. One of the characteristics of the present invention is that the storage capacitor and the pixel transistor are simultaneously formed to have the same structure using the same process. The storage capacitor exhibits good static capacitance and static characteristics since it is configured to have a structure that the dielectric layer 59 made of the same material as the gate insulating layer of the pixel transistor is mounted between the crystalline silicon layer 52P with good electron mobility and the capacitor electrode 57 made of the same material as the gate electrode.

As shown in FIG. 5n, an intermediate insulating layer 62 is formed after the active layer of the transistor in the pixel and peripheral regions of the substrate has been crystallized. The intermediate insulating layer 62 is formed by depositing silicon oxide, silicon nitride, silicon oxynitride or composite layer thereof to thickness of 1,000 to 15,000 Å, more preferably 3,000 to 7,000 Å, using the deposition methods such as PECVD, LPCVD, APCVD, ECR CVD or sputtering.

FIG. 5o shows a state where a contact electrode 63 is formed. Referring to FIG. 5o, a contact hole is formed by wet or dry etching the intermediate insulating layer using the pattern formed by the photolithography as a mask. The contact electrode 63 for connecting the source, drain and gate of the transistor to external circuits is then formed. The contact electrode 63 is formed by depositing the metal or the conductive material such as doped crystalline silicon onto the entire intermediate insulating layer to thickness of 500 to 10,000 Å, more preferably 2,000 to 6,000 Å, using the sputtering, evaporation, CVD method, and the like, and then patterning the metal or the conductive material to have a desired shape through the dry or wet etching method.

FIG. 5p shows a structure of a complete OELD panel when the pixel region of the OELD has been formed of the N-TFT, as described in the preferred embodiment. After an insulating film 64 for covering the contact electrode has been formed and then patterned, a metal electrode 65 serving as a cathode electrode for applying the electric field to the organic electro luminescent material 66 of the unit pixel of the OELD is formed in the pixel region to come into contact with a drain electrode of the pixel transistor. Then, an insulating layer 67 including the organic luminescent material 66 is formed on the metal electrode 65, and an ITO transparent electrode serving as an anode electrode is formed on an electro luminescent layer. As such, the OELD panel in which the N-type TFT is used as the pixel transistor has a top emission structure since the ITO electrode is formed on the organic electro luminescent material.

FIG. 5q shows a structure of the complete OELD panel when the pixel region of the OELD is formed of the P-TFT, contrary to FIG. 5p. In FIG. 5q, after the insulating film 64 for covering the contact electrode has been formed and then patterned, the transparent ITO electrode 68 serving as the anode electrode for applying the electric field to the organic luminescent material 66 of the OELD unit pixel is formed in the pixel region to come into contact with the drain electrode of the pixel transistor. Then, the insulating layer 67 including the organic luminescent material 66 is formed on the transparent ITO electrode, and the metal electrode serving as the cathode electrode is formed on the insulating layer 67. As such, the OELD panel in which the P-type TFT is used as the pixel transistor has a bottom emission structure since the ITO electrode is formed below the organic electro luminescent material.

According to the aforementioned processes, the polycrystalline silicon addressing TFT having two gate electrodes, the storage capacitor and the pixel driving TFT are simultaneously formed in the pixel region of the TFT panel for the OELD by using the MILC, whereas the polycrystalline silicon driving transistor such as the CMOS is simultaneously formed in the peripheral region by using a low-temperature process. In the TFT panel fabricated as such, the off current of the pixel transistor can be effectively reduced since the dual electrodes are formed in the addressing TFT of the pixel region.

Although the present invention has been described with reference to a preferred embodiment, it is merely an example of the present invention but should not be construed to limit the technical scope of the present invention. It is apparent to those skilled in the art that the present invention can be modified or changed in various modes within the scope of the present invention.

For example, although it has been described in the preferred embodiment that two gate electrodes are formed in the transistor in the pixel region, it should be noted that more gate electrodes can be formed, if necessary, within the scope of the present invention. Further, although it has been described that the CMOS is formed in the peripheral region, the driving circuit comprising the various types of the thin film transistors such as P-MOS, N-MOS and CMOS or combination thereof can be formed in the peripheral region. In addition, although it has been described in the preferred embodiment that a single gate electrode is formed in the driving transistor, two or more gate electrodes can be formed therein. Furthermore, although it has been described that the gate patterns of the N-TFT and the P-TFT are separately formed and impurities are also separately injected into the N-TFT and the P-TFT, it should be noted that the gate patterns may be simultaneously formed and the N-TFT and the P-TFT may be formed in such a manner that the P-FTF region is masked by the photoresist etc. when the N-TFT impurity is injected therein, and that the N-FTF region is also masked by the photoresist when the N-TFT impurity is injected therein. Of course, it is apparent that these additional mask processes are not required if all the TFTs such as the pixel transistor and the driving transistor are to be formed using only one type of TFT. Moreover, although it has been described above that the electrode of the storage capacitor is formed from the crystalline silicon, the electrode can be replaced by the other layer such as the metal layer. It is also apparent to those skilled in the art that the dielectric layer of the storage capacitor may be formed using a layer made of a material different from that of the gate insulating layer, e.g. the intermediate insulating layer.

As described above, according to the present invention, there is an advantage in that the pixel transistor including the addressing transistor and pixel driving transistor, the storage capacitor and the driving device can be simultaneously formed in the TFT panel, using the MILC, at low temperature at which the substrate for use in a display device such as the OELD cannot be damaged. Further, there is another advantage in that the TFT panel of the present invention can meet the on current characteristic required in the pixel transistor and the driving device of the LCD and can also effectively reduce the off current of the pixel transistor below a required level by forming two or more gates in the pixel transistor, particularly the addressing transistor. In addition, there is a further advantage in that the low-concentration doping region and the metal offset region can be formed in the transistors of the TFT panel through a simple process, and thus, the operating characteristics of the pixel transistor and the driving device can be further improved.

What is claimed is:

1. A crystalline silicon thin film transistor (TFT) panel for use in an organic electro luminescent display (OELD), comprising:
a transparent substrate including a pixel region having a plurality of unit pixels and a peripheral region;
a pixel transistor which is formed at every unit pixel of the pixel region in the substrate and includes two or more TFTs each having crystalline silicon active layer, a gate insulating layer and a gate electrode, said active layer being crystallized by metal induced lateral crystallization (MILC);
a storage capacitor formed at every unit pixel of the substrate; and
a plurality of driving transistors which are formed in the peripheral region of the substrate and include a crystalline silicon active layer crystallized by the MILC, a gate insulating layer and a gate electrode,
wherein two or more gate electrodes are formed in at least one TFT of the pixel transistor.

2. The TFT panel as claimed in claim 1, wherein the pixel transistor includes at least one addressing TFT and at least one pixel driving TFT, and two or more gate electrodes are formed in the addressing TFT for directly supplying current to the storage capacitor.

3. The TFT panel as claimed in claim 1, wherein the pixel transistor comprises an N-MOS or P-MOS and the driving transistor comprises a CMOS.

4. The TFT panel as claimed in claim 1, wherein two or more gate electrodes are formed in the pixel transistor and the peripheral TFT.

5. The TFT panel as claimed in claim 1, wherein at least one gate insulating layer in the pixel transistor is wider than the gate electrode, and a low-concentration doped region having impurity concentration of 1E14/cm² or lower is formed around a channel region of at least one addressing TFT by performing low-energy high-concentration doping using the gate insulating layer as a mask and high-energy low-concentration doping using the gate electrode as the mask.

6. The TFT panel as claimed in claim 1, wherein the MILC is performed through a process of applying a metal for inducing the MILC to an amorphous silicon layer and annealing the layer in a state where the gate insulating layer of the at least one pixel transistor is formed to be wider than the gate electrode and then the gate electrode and the gate insulating layer are used as a mask.

7. The TFT panel as claimed in claim 6, wherein the metal for inducing the MILC is applied by depositing at least one of Ni, Pd, Ti, Ag, Au, Al, Sn, Sb, Cu, Co, Cr, Mo, Tr, Ru, Rh, Cd and Pt to thickness of 1 to 200 Å using sputtering, evaporation or CVD method, and the annealing process is performed in a furnace at a temperature of 400 to 600° C. for 0.1 to 50 hours.

8. The TFT panel as claimed in claim 1, wherein a shield layer for preventing impurity diffusion is formed on the transparent substrate before the pixel transistor, the storage capacitor and the driving transistor are formed.

9. The TFT panel as claimed in claim 1, further comprising an intermediate insulating layer and a patterned contact electrode, which are formed on the pixel transistor, the storage capacitor and the driving transistor.

10. The TFT panel as claimed in claim 9, further comprising an insulating film for covering the contact electrode, a metal electrode for applying an electric field to an organic electro luminescent material of the unit pixel in the pixel region of the OELD, an insulating layer including the organic electro luminescent material, and an ITO transparent electrode.

11. The TFT panel as claimed in claim 1, wherein the storage capacitor includes an crystalline silicon layer crystallized by the MILC, and a dielectric layer and a capacitor electrode which are sequentially formed on the crystalline silicon layer; the crystalline silicon layer of at least one pixel transistor and the crystalline silicon layer of the storage capacitor are connected with each other; the gate insulating layer of the pixel transistor and the dielectric layer of the capacitor are simultaneously formed from the same material; and the gate electrode of the pixel transistor and the capacitor electrode are simultaneously formed from the same material.
